(19) United States
(12) Patent Application Publication
(10) Pub. No.: US 2025/0062254 A1
(43) Pub. Date: Feb. 20, 2025

(54) METHOD FOR MANUFACTURING ALUMINUM PAD OF SEMICONDUCTOR CHIP

(71) Applicant: Shanghai Huali Integrated Circuit Corporation, Shanghai (CN)

(72) Inventors: Tianquan SHI, Shanghai (CN); Zhenghong LIU, Shanghai (CN); Ruisheng QI, Shanghai (CN); Guanqun HUANG, Shanghai (CN); Haoyu CHEN, Shanghai (CN)

(73) Assignee: Shanghai Huali Integrated Circuit Corporation, Shanghai (CN)

(21) Appl. No.: 18/614,346

(22) Filed: Mar. 22, 2024

(30) Foreign Application Priority Data
Aug. 15, 2023 (CN) 202311027398.3

(51) Int. Cl. H01L 23/00; C23C 14/06; C23C 14/14; G03F 7/00

(52) U.S. Cl. CPC H01L 24/03; C23C 14/0641; C23C 14/14; G03F 7/0035; H01L 24/05; H01L 2224/02313; H01L 2224/0345; H01L 2224/0348; H01L 2224/03614; H01L 2224/05166; H01L 2224/05181; H01L 2224/05624; H01L 2924/04941; H01L 2924/04953

(57) ABSTRACT

This application discloses a method for manufacturing an aluminum pad of a semiconductor chip, an upper surface of a semiconductor substrate is a top metal layer which has been grown, a passivation layer with a SiN-OX-SiN-OX four-layer structure from bottom to top is deposited on the top metal layer, the passivation layer in a via area is removed and the passivation layer outside the via area is reserved, an aluminum pad layer process is performed, remove aluminum in areas not requiring aluminum and reserve aluminum in the via area to complete the fabrication of the aluminum pad. This application can not only solve the side effect of aluminum pad crystal from the source on the premise of ensuring the functionality of the aluminum pad, but also save one mask and one photo layer, the cost is low, and the process is stable.

### CROSS-REFERENCES TO RELATED APPLICATIONS

This application claims priority to Chinese patent application No. CN202311027398.3 filed on Aug. 15, 2023, and entitled “METHOD FOR MANUFACTURING ALUMINUM PAD OF SEMICONDUCTOR CHIP”, the disclosure of which is incorporated herein by reference in entirety.

### TECHNICAL FIELD

This application relates to a semiconductor manufacturing technology, in particular to a method for manufacturing an aluminum pad of a semiconductor chip.

### BACKGROUND

As an interface between an internal circuit and an external wire of a chip, pad has a significant influence on the yield and reliability of the chip. On the one hand, the surface condition of the pad may influence the quality of wire bonding. Defects on the surface of the pad may cause wire bonding failure or poor reliability, thereby reducing the yield of the subsequent package testing and even affecting the reliability of the final product. On the other hand, since the pad manufacturing process is located at the tail end of the entire wafer manufacturing process, scrapped wafers caused by defects on the pad surface are nearly finished products, making the cost of scrapping very high. Therefore, studying the defects in pad manufacturing has a positive significance to ensuring the quality of chip production, improving the overall yield and reliability of chip manufacturing, and reducing the risk of product scrapping.

Aluminum metal, due to its excellent oxidation resistance and welding performance, is still retained as a material for manufacturing chip external interconnections and pads in process nodes. Crystal defects on aluminum pads are a type of crystal defect caused by the erosion of fluorine elements on the surface. Crystal defects are damaging defects that may cause wire bonding failure in the packaging process, seriously affecting the yield and reliability of chips. There are many reasons for the formation of pad crystal defects. In addition to the influence caused by transportation packaging, chip packaging, and other processes, the introduction of fluorine elements into pads during wafer processing is an important reason.

When aluminum is used as a surface metal layer, after the passivation layer on the aluminum surface is etched in the semiconductor technology to open the pad window, the aluminum pad is exposed to air and is prone to electrochemical reactions with water vapor and fluorine in the environment to form crystal defects such as fluorine oxides.

For the Al—TiN stack structure formed by the conventional APL (Aluminum Pad Layer) process, Al will be covered by TiN to provide initial protection. The conventional APL (Aluminum Pad Layer) process requires a Cover-Etch (cover etching) process to remove TiN on the surface of the Al pad area when defining the Al pad area. Currently, the industry's method of removing TiN requires the introduction of fluorine-containing polymers. However, if the fluorine-containing polymers are not cleaned up in time after TiN is removed, fluorine residue is prone to occur, and when Al is exposed to air in the future, combined with the air environment (including water vapor, fluorine and other substances), electrochemical reactions will occur to form crystals such as fluorine oxides, which can easily cause Al pad crystal on the surface of the newly exposed Al pad, greatly increasing the resistance of the Al pad, causing functional failure of the Al pad, and seriously affecting the chip performance.

### BRIEF SUMMARY

The technical problem to be solved by this application is to provide a method for manufacturing an aluminum pad of a semiconductor chip can not only solve the side effect of Al pad crystal from the source on the premise of ensuring the functionality of the aluminum pad, but also save one mask and one photo layer, the cost is low, and the process is stable.

In order to solve the technical problem, this application provides a method for manufacturing an aluminum pad of a semiconductor, including the following steps:
S1: providing a semiconductor substrate, an upper surface of the semiconductor substrate being a top metal layer 100 which has been grown;
S2: depositing a passivation layer on the top metal layer 100, the passivation layer being a SiN-OX-SiN-OX four-layer structure from bottom to top;
S3: removing the passivation layer in a via area and reserving the passivation layer outside the via area;
S4: performing an aluminum pad layer process; and
S5: performing a photolithographic process and etching to remove aluminum in areas not requiring aluminum and reserve aluminum in the via area to complete the fabrication of the aluminum pad.

According to some embodiments, the semiconductor chip is a SONOS memory.

According to some embodiments, in step S3, the via area is defined through an RV process, the passivation layer in the via area is removed, and the passivation layer outside the via area is reserved.

According to some embodiments, the RV process includes redistribution via photoresist development and redistribution via etching;
the via area is defined by performing redistribution via photoresist 105 development;
a redistribution via etching process is performed to remove the passivation layer in the via area and reserve the passivation layer outside the via area.

According to some embodiments, the aluminum pad layer process includes aluminum line formation and aluminum deposition.

According to some embodiments, in step S2, depositing a passivation layer on the top metal layer 100 includes the following steps:
S21: depositing a first SiN layer 101 on the top metal layer 100;
S22: depositing a first OX layer 102 on the first SiN layer 101;
523: depositing a second SiN layer 103 on the first OX layer 102; and
S24: depositing a second OX layer 104 on the second SiN layer 103.

According to some embodiments, the first SiN layer 101, the first OX layer 102, the second SiN layer 103 and the second OX layer 104 are formed by adopting chemical vapor deposition, physical vapor deposition, or atomic layer deposition.

According to some embodiments, the thickness of the first SiN layer 101 is 800 nm-1200 nm;
the thickness of the first OX layer 102 is 6800 nm-7200 nm;
the thickness of the second SiN layer 103 is 3800 nm-4200 nm;
the thickness of the second OX layer 104 is 1000 nm-5000 nm.

According to some embodiments, in step S4, the aluminum pad layer process adopts physical vapor deposition to firstly deposit a TaN/Ti/TiN layer 106, and then deposit an Al layer 107.

According to some embodiments, the top metal layer 100 is metal Cu.

The method for manufacturing the aluminum pad of the semiconductor chip in this application does not require a cover etching process (Cover-ET loop), does not require the deposition of a blocking layer thin film on the Al surface as the cover of the chip, does not require the area re-definition of the formed Al pad to remove the cover of the chip, and does not introduce fluorine elements/ions. Therefore, there is no phenomenon of Al pad crystal. Moreover, during aluminum pad layer (APL) etching (APL-ET), the top OX (oxide) layer of the passivation layer with the SiN-OX-SIN-OX four-layer structure can also provide protection, thus completely maintaining the sandwich structure of the lower three layers of SiN-OX-SiN, reserving the same parts as the conventional process, and causing no other side effects. The method for manufacturing the aluminum pad of the semiconductor chip, by combining the structural characteristics of the device and skipping the entire cover loop, can not only solve the side effect of Al pad crystal from the source on the premise of ensuring the functionality of the aluminum pad, but also save one mask and one photo layer, the cost is low, and the process is stable.

### BRIEF DESCRIPTION OF THE DRAWINGS

In order to describe the technical solutions in this application more clearly, the following will briefly introduce the drawings needed in this application. It is obvious that the drawings in the following description are only some embodiments of this application. Those skilled in the art may obtain other drawings from these drawings without contributing any inventive labor.

FIG. 1 illustrates a cross-sectional schematic diagram of depositing a SiN-OX-SiN-OX four-layer structure on a top metal layer of an aluminum pad of a semiconductor chip in a method for manufacturing an aluminum pad of a semiconductor chip according to an embodiment of this application.

FIG. 2 illustrates a cross-sectional schematic diagram of defining an area requiring growth of Al through a photolithographic process in a method for manufacturing an aluminum pad of a semiconductor chip according to an embodiment of this application.

FIG. 3 illustrates a cross-sectional schematic diagram of removing a passivation layer in an area requiring growth of Al in a method for manufacturing an aluminum pad of a semiconductor chip according to an embodiment of this application.

FIG. 4 illustrates a cross-sectional schematic diagram of performing an aluminum pad layer process in a method for manufacturing an aluminum pad of a semiconductor chip according to an embodiment of this application.

FIG. 5 illustrates a cross-sectional schematic diagram of defining a via area through a photolithographic process in a method for manufacturing an aluminum pad of a semiconductor chip according to an embodiment of this application.

FIG. 6 illustrates a cross-sectional schematic diagram of removing excess Al outside a via area through etching in a method for manufacturing an aluminum pad of a semiconductor chip according to an embodiment of this application.

### DETAILED DESCRIPTION OF THE EMBODIMENTS

The technical solutions in the embodiments of this application will be clearly and completely described below with reference to the drawings in the embodiments of this application.

Apparently, the described embodiments are merely some rather than all of the embodiments of this application. All other embodiments obtained by those skilled in the art based on the embodiments of this application without contributing any inventive labor shall still fall within the scope of protection of this application.

Words such as “first”, “second” and the like used in this application do not indicate any order, quantity, or importance, but are only intended to distinguish different components. Words such as “comprising”, “including” and the like refer to a component or object that appears before the word including those listed after the word and their equivalents, without excluding other components or objects. Words such as “connecting”, “connected” and the like are not limited to physical or mechanical connection, but can include electrical connection, whether direct or indirect. “Up”, “down”, “left”, “right”, “front”, “back” and the like are only intended to represent relative positional relationships. When the absolute position of a described object changes, the relative positional relationship may also change accordingly.

It is to be understood that, without conflict, the embodiments and features in the embodiments of this application may be freely combined with each other.

### Embodiment 1

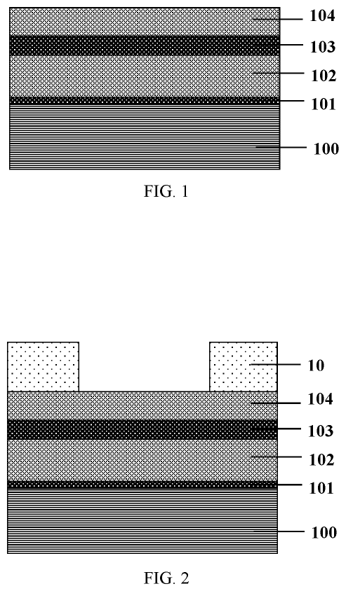

Referring to FIG. 1 to FIG. 6, a method for manufacturing an aluminum pad of a semiconductor chip includes the following steps:

In S1, a semiconductor substrate is provided. An upper surface of the semiconductor substrate is a top metal layer 100 which has been grown.

In S2, a passivation layer is deposited on the top metal layer 100. The passivation layer is a SiN-OX-SiN-OX four-layer structure from bottom to top, as illustrated in FIG. 1.

In S3, the passivation layer in a via area is removed and the passivation layer outside the via area is reserved, as illustrated in FIG. 2 and FIG. 3.

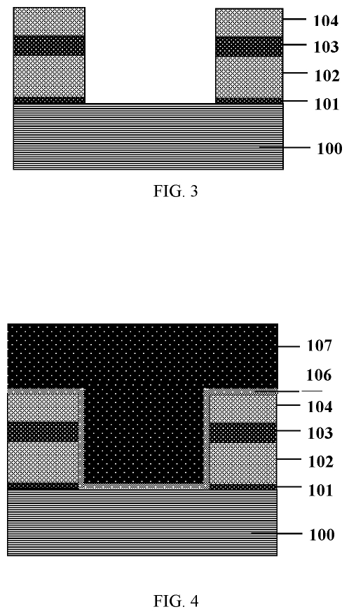

In S4, an Aluminum Pad Layer (APL) process is performed, as illustrated in FIG. 4.

In S5, a photolithographic process and etching are performed to remove excess Al in areas not requiring Al (outside the via area) and reserve Al in the via area to complete the fabrication of the Al pad.

According to some embodiments, the semiconductor chip is a SONOS (Silicon-Oxide-Nitride-Oxide-Silicon) memory.

In the method for manufacturing the aluminum pad of the semiconductor chip in embodiment 1, oxides and nitrides are deposited on the surface of the top metal layer 100 to form a passivation layer with a SiN-OX-SiN-OX four-layer structure. The lower three layers of the passivation layer are a conventional SiN-OX-SiN sandwich structure, and the top layer of the passivation layer is an oxide (OX) cover, which can protect the sandwich structure at the bottom from being damaged during Aluminum Pad Layer (APL) etching (APL-ET). Subsequently, an RV (Redistribution Via)process is performed on the passivation layer to define a via area. The passivation layer in the via area is removed, and the passivation layer outside the via area is reserved. Then, an Aluminum Pad Layer (APL) process is performed. Finally, the excess Al in areas not requiring Al is removed by etching, and Al in the via area is reserved to form an Al pad that can be directly used or tested (such as for various electrical tests of wafers). At this time, the structure around the Al pad is different from that around the Al pad area grown by conventional processes (the top layer is an oxide (OX) cover), and there is no need to grow another TiN layer on the Al surface to protect Al. In addition, the exposed Al can form a cover on its own due to its surface being easily oxidized by oxygen. However, during testing and use, this cover is formed spontaneously and has a small film thickness, making it easy to penetrate. Therefore, it will not affect testing and use.

The method for manufacturing the aluminum pad of the semiconductor chip in embodiment 1 does not require a cover etching process (Cover-ET loop), does not require the deposition of a blocking layer thin film on the Al surface as the cover of the chip, does not require the area re-definition of the formed Al pad to remove the cover of the chip, and does not introduce fluorine elements/ions. Therefore, there is no phenomenon of Al pad crystal. Moreover, during aluminum pad layer (APL) etching (APL-ET), the top OX (oxide) layer of the passivation layer with the SiN-OX-SIN-OX four-layer structure can also provide protection, thus completely maintaining the sandwich structure of the lower three layers of SiN-OX-SiN, reserving the same parts as the conventional process, and causing no other side effects. The method for manufacturing the aluminum pad of the semiconductor chip in embodiment 1, by combining the structural characteristics of the device and skipping the entire cover loop, can not only solve the side effect of Al pad crystal from the source on the premise of ensuring the functionality of the aluminum pad, but also save one mask and one photo layer, the cost is low, and the process is stable.

### Embodiment 2

Based on the method for manufacturing the aluminum pad of the semiconductor chip in embodiment 1, in step S3, the via area is defined through an RV (Redistribution Via) process, the passivation layer in the via area is removed, and the passivation layer outside the via area is reserved.

According to some embodiments, the RV (Redistribution Via) process includes RV-Photo (redistribution via photoresist 105 development) and RV-Etch (redistribution via etching).

An area requiring growth of Al is defined by performing RV-Photo (redistribution via photoresist 105 development), as illustrated in FIG. 2.

The passivation layer in the via area is removed through an RV-Etch (redistribution via etching) process to expose the top metal layer 100 in the via area and reserve the passivation layer in areas not requiring growth of Al outside the via area, as illustrated in FIG. 3.

According to some embodiments, the Aluminum Pad Layer (APL) process includes Al-Liner (Al line) formation and Al-Dep (Al deposition).

### Embodiment 3

Based on the method for manufacturing the aluminum pad of the semiconductor chip in embodiment 1, in step S2, depositing a passivation layer on a top metal layer 100 includes the following steps:
S21: depositing a first SiN layer 101 on the top metal layer 100;
S22: depositing a first OX layer 102 on the first SiN layer 101;
S23: depositing a second SiN layer 103 on the first OX layer 102; and
S24: depositing a second OX layer 104 on the second SiN layer 103 as illustrated in FIG. 1.

According to some embodiments, the first SiN layer 101, the first OX layer 102, the second SiN layer 103 and the second OX layer 104 are formed by adopting chemical vapor deposition, Physical Vapor Deposition (PVD) or atomic layer deposition.

According to some embodiments, the thickness of the first SiN layer 101 is 800 nm-1200 nm (for example, 1000 nm).

The thickness of the first OX layer 102 is 6800 nm-7200 nm (for example, 7000 nm).

The thickness of the second SiN layer 103 is 3800 nm-4200 nm (for example, 4000 nm).

The thickness of the second OX layer 104 is 1000 nm-5000 nm, and 2000 nm-4000 nm (for example, 3000 nm) according to some embodiments.

### Embodiment 4

Based on the method for manufacturing the aluminum pad of the semiconductor chip in embodiment 1, in step S4, the aluminum pad layer process adopts a Physical Vapor Deposition (PVD) process to firstly deposit a TaN/Ti/TiN layer 106, and then deposit an Al layer 107, as illustrated in FIG. 4.

According to some embodiments, the top metal layer 100 is metal Cu.

### Embodiment 5

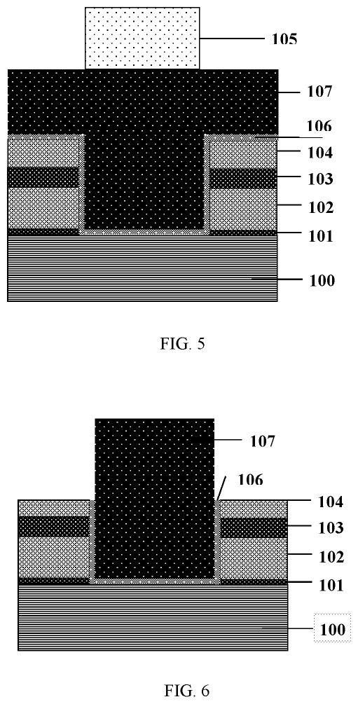

Based on the method for manufacturing the aluminum pad of the semiconductor chip in embodiment 1, in step S5, firstly a photolithographic process is performed on photoresist 105 to define a via area, as illustrated in FIG. 5; and then, etching is performed to remove excess Al in areas outside the via area and reserve Al in the via area, as illustrated in FIG. 6, to complete the fabrication of the Al pad.

In the method for manufacturing the aluminum pad of the semiconductor chip in embodiment 5, excess Al in areas outside the via area is all removed and Al in the via area is reserved. Due to the need to ensure that there is no Al residue in other areas, it is necessary to etch down as much as possible to a certain depth. At this time, the top layer OX (oxide) of the passivation layer acts as a sacrificial layer, protecting the underlying three-layer structure by sacrificing the thickness of the top layer OX (oxide), so as to maintain the basic performance of the Al pad.

What are described above are only exemplary embodiments of this application, and are not intended to limit this application. Any modifications, equivalent replacements, improvements and the like made within the spirit and principle of this application shall be all included in the scope of protection of this application.

What is claimed is:

1. A method for manufacturing an aluminum pad of a semiconductor chip, comprising the following steps:
S1: providing a semiconductor substrate, an upper surface of the semiconductor substrate being a top metal layer (100) which has been grown;
S2: depositing a passivation layer on the top metal layer (100), the passivation layer being a SiN-OX-SiN-OX four-layer structure from bottom to top;
S3: removing the passivation layer in a via area and reserving the passivation layer outside the via area;
S4: performing an aluminum pad layer process; and
S5: performing a photolithographic process and etching to remove aluminum in areas not requiring aluminum and reserve aluminum in the via area to complete the fabrication of the aluminum pad.

2. The method for manufacturing the aluminum pad of the semiconductor chip according to claim 1, wherein
the semiconductor chip is a SONOS memory.

3. The method for manufacturing the aluminum pad of the semiconductor chip according to claim 1, wherein
in step S3, the via area is defined through an RV process, the passivation layer in the via area is removed, and the passivation layer outside the via area is reserved.

4. The method for manufacturing the aluminum pad of the semiconductor chip according to claim 3, wherein
the RV process comprises redistribution via photoresist development and redistribution via etching;
the via area is defined by performing redistribution via photoresist (105) development; and
a redistribution via etching process is performed to remove the passivation layer in the via area and reserve the passivation layer outside the via area.

5. The method for manufacturing the aluminum pad of the semiconductor chip according to claim 1, wherein
the aluminum pad layer process comprises aluminum line formation and aluminum deposition.

6. The method for manufacturing the aluminum pad of the semiconductor chip according to claim 1, wherein
in step S2, depositing a passivation layer on the top metal layer (100) comprises the following steps:
S21: depositing a first SiN layer (101) on the top metal layer (100);
S22: depositing a first OX layer (102) on the first SiN layer (101);
S23: depositing a second SiN layer (103) on the first OX layer (102); and
S24: depositing a second OX layer (104) on the second SiN layer (103).

7. The method for manufacturing the aluminum pad of the semiconductor chip according to claim 6, wherein
the first SiN layer (101), the first OX layer (102), the second SiN layer (103) and the second OX layer (104) are formed by adopting chemical vapor deposition, physical vapor deposition, or atomic layer deposition.

8. The method for manufacturing the aluminum pad of the semiconductor chip according to claim 6, wherein
the thickness of the first SiN layer (101) is 800 nm-1200 nm;
the thickness of the first OX layer (102) is 6800 nm-7200 nm;
the thickness of the second SiN layer (103) is 3800 nm-4200 nm; and
the thickness of the second OX layer (104) is 1000 nm-5000 nm.

9. The method for manufacturing the aluminum pad of the semiconductor chip according to claim 1, wherein
in step S4, the aluminum pad layer process adopts physical vapor deposition to firstly deposit a TaN/Ti/TiN layer (106), and then deposit an Al layer (107).

10. The method for manufacturing the aluminum pad of the semiconductor chip according to claim 1, wherein
the top metal layer (100) is metal Cu.
